(19) United States
(12) Patent Application Publication
(10) Pub. No.: US 2024/0147814 A1
(43) Pub. Date: May 2, 2024

(54) DISPLAY DEVICE

(71) Applicant: SAMSUNG DISPLAY CO., LTD., Yongin-si (KR)

(72) Inventors: KISANG YOO, Yongin-si (KR); YOUNGSU KIM, Yongin-si (KR); JISOO KIM, Yongin-si (KR); DONGJIN PARK, Yongin-si (KR); CHEULJIN PARK, Yongin-si (KR); KYOUNGAH LEE, Yongin-si (KR); SUNGKOOK LEE, Yongin-si (KR)

(21) Appl. No.: 18/226,249

(22) Filed: Jul. 25, 2023

(30) Foreign Application Priority Data
Oct. 28, 2022 (KR) 10-2022-0140960

(51) Int. Cl. H10K 59/80

(52) U.S. Cl. CPC H10K 59/873; H10K 59/12

(57) ABSTRACT

A display device includes a display panel and a protective film attached to a rear surface of the display panel through an adhesive layer. The display panel includes a first side extended in a first direction, a second side extended in a second direction intersecting the first direction, and a panel corner portion connecting the first side and the second side and having a curvature. The protective film includes recessed patterns disposed adjacent to the panel corner portion and overlapping the adhesive layer.

This application claims priority to Korean Patent Application No. 10-2022-0140960 filed on Oct. 28, 2022, and all the benefits accruing therefrom under 35 U.S.C. § 119, the entire contents of which are herein incorporated by reference.

### BACKGROUND

The disclosure herein relates to a display device, and more particularly, to a display device in which a window and a display panel are coupled.

Multimedia electronic devices such as televisions, mobile phones, tablets, navigation system units, and game consoles may include a display device for displaying images. More recently, display devices of various shapes are being developed. For example, a display device may display images through a curved display surface.

The display device may be manufactured by laminating a display module including a display panel, and a window. The curved display device is provided by using a display module that is adhered to a window having a curved surface. However, in the lamination process, the display module may be wrinkled during the process of adhering the display module to a portion where the window has the curved surface.

### SUMMARY

The present disclosure provides a display device which has improved reliability.

The present disclosure also provides a display device which prevents a display panel from being wrinkled or damaged during the process of adhering the display panel to a window.

An embodiment includes providing a display device including a display panel, and a protective film adhered to a rear surface of the display panel through an adhesive layer. In an embodiment, the display panel may include a first side extended in a first direction, a second side extended in a second direction intersecting the first direction, and a panel corner portion connecting the first side and the second side and having a curvature. In an embodiment, the protective film may include recessed patterns disposed adjacent to the panel corner portion and overlapping the adhesive layer.

In an embodiment, the recessed patterns may be disposed at an inner side and at a distance dl from another side surface of the protective film.

In an embodiment, the recessed patterns may be extended to an outer side surface of the protective film on a plane.

In an embodiment, the recessed patterns may be disposed within a region of ±20 degrees or more based on a line connecting a center of curvature from a point of maximum curvature of the panel corner portion.

In an embodiment, each of the recessed patterns may have a stripe shape in which the recessed patterns are extended along a direction intersecting each of the first direction and the second direction on a plane.

In an embodiment, each of the recessed patterns may be extended in a direction toward a center of curvature of the panel corner portion from one point of an edge of the panel corner portion.

In an embodiment, an angle between reference lines parallel to extension directions of recessed patterns adjacent to each other among the recessed patterns may be 3 degrees or more.

In an embodiment, the recessed patterns may include first to n-th recessed patterns, wherein an angle between a first reference line parallel to an extension direction of the first recessed pattern and a n-th reference line parallel to an extension direction of the n-th recessed pattern may be 65 degrees or more. Here, the n is a natural number of 2 or greater.

In an embodiment, the recessed patterns may have a mesh shape in which the recessed patterns are connected by intersecting each other on a plane.

In an embodiment, in a thickness direction, a depth of each of the recessed patterns may be equal to or less than a thickness of the protective film.

In an embodiment, a width of each of the recessed patterns may be constant along the thickness direction.

In an embodiment, a width of each of the recessed patterns may decrease with proximity to the display panel.

In an embodiment, the display panel may include a main display portion parallel to the first direction and the second direction, a first side display portion extended from the main display portion in the second direction and curved, and a second side display portion extended from the main display portion in the first direction and curved. In an embodiment, the first side and the second side may be respectively defined in the first side display portion and the second side display portion.

In an embodiment, the display panel may include a base layer, a circuit layer disposed on the base layer, a display element layer disposed on the circuit layer and including light emitting elements, and an encapsulation layer disposed on the display element layer, wherein the protective film may be attached to the base layer.

In an embodiment, the display device may further include a light blocking layer disposed below the protective film and overlapping the recessed patterns.

In an embodiment, the display device may further include a window disposed on the display panel, and an adhesive member disposed between the display panel and the window.

In an embodiment, a display device includes a display panel including a panel corner portion having at least one curvature, and a protective film disposed on a rear surface of the display panel and including recessed patterns adjacent to the panel corner portion. In an embodiment, the recessed patterns may be disposed within a region of ±20 degrees or more based on a line connecting a center of curvature from a point of maximum curvature of the panel corner portion.

In an embodiment, the recessed patterns may include first to n-th recessed patterns arranged along one direction, wherein an angle between a first reference line parallel to an extension direction of the first recessed pattern and a n-th reference line parallel to an extension direction of the n-th recessed pattern may be 65 degrees or more. Here, the n is a natural number of 2 or greater.

In an embodiment, an angle between reference lines parallel to extension directions of recessed patterns adjacent to each other among the first to n-th recessed patterns may be 3 degrees or more.

In an embodiment, the recessed patterns may have a stripe shape or a mesh shape.

### BRIEF DESCRIPTION OF THE FIGURES

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a perspective view of a display device according to an embodiment of the invention;

FIG. 2 is an exploded perspective view of a display device according to an embodiment of the invention;

FIG. 3 is a cross-sectional view of a display panel according to an embodiment of the invention;

FIG. 4 is a plan view of a protective film according to an embodiment of the invention;

FIG. 5A and FIG. 5B are plan views of a protective film in which one region AA′ of FIG. 4 is enlarged;

FIG. 6A to FIG. 6C are plan views of a protective film according to an embodiment of the invention;

FIG. 7A and FIG. 7B are cross-sectional views of a display device according to an embodiment of the invention;

FIG. 8A is a plan view of a display device according to an embodiment of the invention;

FIG. 8B is a cross-sectional view of a display device according to an embodiment of the invention;

FIG. 9A is a plan view of a protective film according to an embodiment of the invention; and

FIG. 9B and FIG. 9C are plan views of a protective film according to a comparative embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the present disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents. The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the elements shown in the drawings. The terms are used as a relative concept and are described with reference to the direction indicated in the drawings.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art and should not be interpreted in too ideal a sense or an overly formal sense unless explicitly defined herein.

Hereinafter, a display device according to an embodiment of the invention will be described with reference to the accompanying drawings.

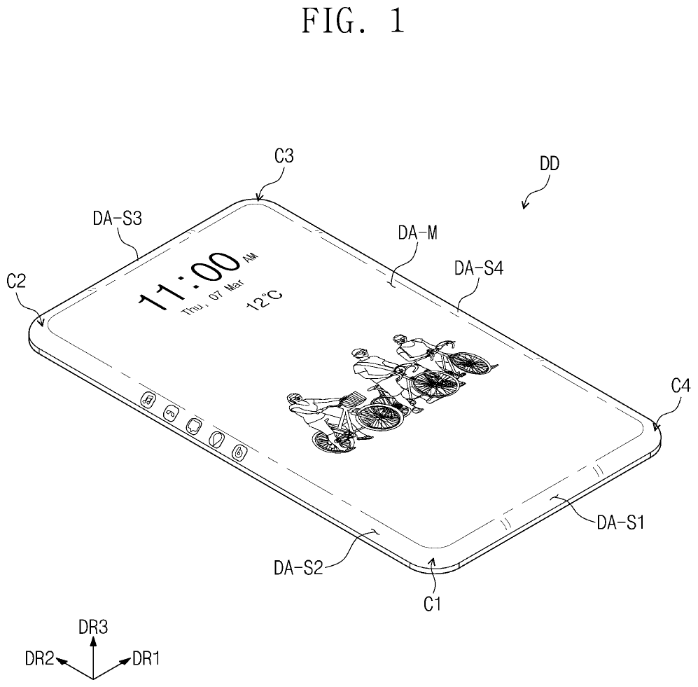

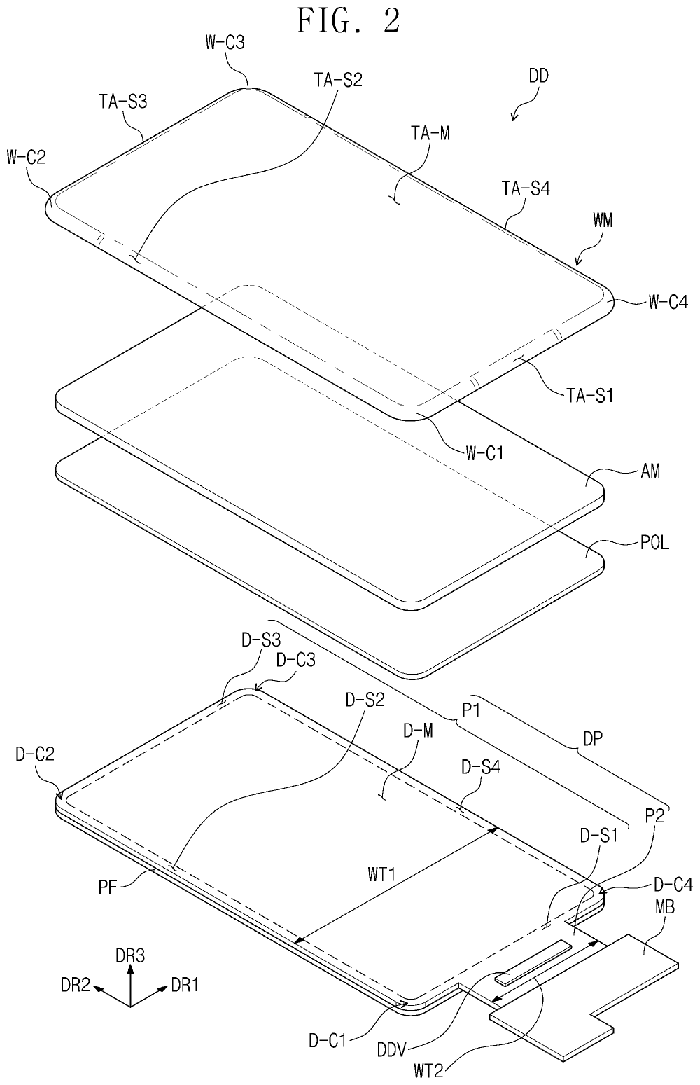

FIG. 1 is a perspective view of a display device DD according to an embodiment of the invention. FIG. 2 is an exploded perspective view of the display device DD illustrated in FIG. 1.

Referring to FIG. 1 and FIG. 2, the display device DD may be a device activated in accordance with an electrical signal and displaying images. For example, the display device DD may include a device such as a monitor, a mobile phone, a tablet, a navigation system unit, and a game console. However, embodiments of the display device DD are exemplary, and the display device DD is not limited to any one thereof without departing from the invention. In the present embodiment, the display device DD is exemplarily illustrated as a mobile phone.

In the display device DD, a display region may be defined. The display device DD may display an image through the display region and may receive an external input. The display region of the display device DD may include a main display region DA-M and first to fourth sub-display regions DA-S1, DA-S2, DA-S3, and DA-S4.

The main display region DA-M may be substantially parallel to a plane defined by a first direction DR1 and a second direction DR2. However, the embodiment of the invention is not limited thereto, and the main display region DA-M may have a shape concavely or convexly curved based on a plane defined by the first direction DR1 and the second direction DR2.

The main display region DA-M may display the image toward a third direction DR3 intersecting each of the first direction DR1 and the second direction DR2. The third direction DR3 may be defined as a thickness direction of the display device DD. A front surface (or an upper surface) and a rear surface (or a lower surface) of each member constituting the display device DD may oppose each other in the third direction DR3.

In the present disclosure, “on a plane” may be defined as a state viewed in the third direction DR3. In the present disclosure, “on a cross-section” may be defined as a state viewed in the first direction DR1 or the second direction DR2. Meanwhile, directions indicated by the first to third directions DR1, DR2, and DR3 are a relative concept, and may be converted to different directions.

The main display region DA-M may have a rectangular shape which has short sides extended in the first direction DR1, and long sides extended in the second direction DR2. However, the embodiment of the invention is not limited thereto, and the main display region DA-M may have various shapes such as a circular shape, a polygonal shape, or the like, on a plane.

Each of the first to fourth sub-display regions DA-S1, DA-S2, DA-S3, and DA-S4 may be bent from the main display region DA-M. Each of the first to fourth sub-display regions DA-S1, DA-S2, DA-S3, and DA-S4 may be bent with a curvature and may include a curved surface. Curvatures of the first to fourth sub-display regions DA-S1, DA-S2, DA-S3, and DA-S4 may be the same as each other, or at least some thereof may be different from each other without being limited thereto.

The main display region DA-M and the first to fourth sub-display regions DA-S1, DA-S2, DA-S3 and DA-S4 may be adjacent to each other to implement a continuous display region. The first sub-display region DA-S1 and the third sub-display region DA-S3 may each be extended from the short sides of the main display region DA-M which are parallel to the first direction DR1, and the second sub-display region DA-S2 and the fourth sub-display region DA-S4 may each be extended from the long sides of the main display region DA-M which are parallel to the second direction DR2.

The first sub-display region DA-S1 and the third sub-display region DA-S3 are each extended along the first direction DR1 and may be spaced apart in the second direction DR2 with the main display region DA-M interposed therebetween. The second sub-display region DA-S2 and the fourth sub-display region DA-S4 are each extended along the second direction DR2 and may be spaced apart in the first direction DR1 with the main display region DA-M interposed therebetween.

FIG. 1 exemplarily illustrates four sub-display regions DA-S1, DA-S2, DA-S3 and DA-S4 extended from four sides of the main display region DA-M, but the embodiment of the invention is not limited thereto, and the display region of the display device DD may include a sub-display region which is extended from at least one side of the four sides of the main display region DA-M and bent. For example, the display device DD according to an embodiment may include some of the four sub-display regions DA-S1, DA-S2, DA-S3 and DA-S4.

The display device DD may include first to fourth corner portions C1, C2, C3, and C4 which are disposed between the first to fourth sub-display regions DA-S1, DA-S2, DA-S3, and DA-S4 respectively. The first to fourth sub-display regions DA-S1, DA-S2, DA-S3, and DA-S4 and the first to fourth corner portions C1, C2, C3, and C4 are sequentially connected to each other to surround the main display region DA-M.

The first corner portion C1 is disposed between the first sub-display region DA-S1 and the second sub-display region DA-S2 and is the portion connecting the first sub-display region DA-S1 and the second sub-display region DA-S2 which are extended in directions intersecting each other and having a curvature. In an embodiment, the first corner portion C1 may be defined by a curved line that contacts the first sub-display region DA-S1 and the second sub-display region DA-S2 in at least a portion of the plane that contains at least a portion of the first sub-display region DA-S1 and at least a portion of the second sub-display region DA-S2. The second corner portion C2 is disposed between the second sub-display region DA-S2 and the third sub-display region DA-S3 and may be a portion connecting the second sub-display region DA-S2 and the third sub-display region DA-S3 which are extended in directions intersecting each other and having a curvature. In an embodiment, the second corner portion C2 may be defined by a curved line that contacts the second sub-display region DA-S2 and the third sub-display region DA-S3 in at least a portion of the plane that contains at least a portion of the second sub-display region DA-S2 and at least a portion of the third sub-display region DA-S3.

The third corner portion C3 is disposed between the third sub-display region DA-S3 and the fourth sub-display region DA-S4 and may be a portion connecting the third sub-display region DA-S3 and the fourth sub-display region DA-S4 which are extended in directions intersecting each other and having a curvature. In an embodiment, the third corner portion C3 may be defined by a curved line that contacts the third sub-display region DA-S3 and the fourth sub-display region DA-S4 in at least a portion of the plane that contains at least a portion of the third sub-display region DA-S3 and at least a portion of the fourth sub-display region DA-S4. The fourth corner portion C4 is disposed between the fourth sub-display region DA-S4 and the first sub-display region DA-S1 and may be a portion connecting the fourth sub-display region DA-S4 and the first sub-display region DA-S1 which are extended in directions intersecting each other and having a curvature. In an embodiment, the fourth corner portion C4 may be defined by a curved line that contacts the fourth sub-display region DA-S4 and the first sub-display region DA-S1 in at least a portion of the plane that contains at least a portion of the fourth sub-display region DA-S4 and at least a portion of the first sub-display region DA-S1.

The first to fourth corner portions C1, C2, C3, and C4 may respectively correspond to corners of the display device DD. Since each of the first to fourth corner portions C1, C2, C3 and C4 have a curvature, the corners of the display device DD may have a round shape without an angle. In some embodiments, the curvature of the first to the fourth corner portions C1, C2, C3 and C4 may lie in a single 2-dimensional plane (i.e., a plane defined by the directions DR1 and DR2 only). Alternatively, in some embodiments, the curvature of the first to the fourth corner portions C1, C2, C3 and C4 may occur in 3-dimensions (i.e., in multiple planes defined by the directions DR1, DR2 and DR3).

Referring to FIG. 2, the display device DD may include a window WM, a display panel DP, a driver DDV, a circuit board MB, a protective film PF, an anti-reflection layer POL, and an adhesive member AM.

The window WM may be disposed on the display panel DP. The window WM may be coupled to the display panel DP through a lamination process. The window WM may protect the anti-reflection layer POL and the display panel DP from external impacts and scratches by covering the anti-reflection layer POL and the display panel DP.

The window WM may include an optically transparent insulation material. For example, the window WM may include a base film containing a glass or a synthetic resin. The window WM may have a single-layered structure or a multi-layered structure. For example, the window WM of the multi-layered structure may include a plurality of synthetic resin films coupled with an adhesive to the anti-reflection layer POL, or a glass film and a synthetic resin film coupled with an adhesive to the anti-reflection layer POL. The window WM may further include a functional layer such as an anti-fingerprint layer, a phase control layer, or a hard coating layer disposed on the base film. The plurality of synthetic resin films may be the same as each other or alternatively, may each be of a different chemical composition from one another.

The window WM may include a transmission region, and the transmission region of the window WM may correspond in size and area to the display region of the display device DD described above. The transmission region of the window WM may transmit an image output from the display panel DP, and a user may visually recognize the image from the outside of the display device DD. The transmission region of the window WM may include a main transmission surface TA-M and first to fourth side transmission surfaces TA-S1, TA-S2, TA-S3, and TA-S4.

The main transmission surface TA-M may correspond to the main display region DA-M (See FIG. 1). The main transmission surface TA-M may include a plane substantially parallel to the plane defined by the first direction DR1 and the second direction DR2.

Each of the first to fourth side transmission surfaces TA-S1, TA-S2, TA-S3 and TA-S4 may be curved in proportion to the curvature of the main transmission surface TA-M. Therefore, each of the first to fourth side transmission surfaces TA-S1, TA-S2, TA-S3 and TA-S4 may include a curved surface that is parallel to the curvature of the main transmission surface TA-M. The first to fourth side transmission surfaces TA-S1, TA-S2, TA-S3 and TA-S4 may respectively correspond to the first to fourth sub-display regions DA-S1, DA-S2, DA-S3 and DA-S4 described above (See FIG. 1.).

The main transmission surface TA-M and the first to fourth side transmission regions TA-S1, TA-S2, TA-S3 and TA-S4 may be adjacent to each other to implement a continuous transmission region. Each of the first side transmission surface TA-S1 and the third side transmission surface TA-S3 are extended along the first direction DR1 and may be spaced apart from each other in the second direction DR2 with the main transmission surface TA-M interposed therebetween. Each of the second side transmission surface TA-S2 and the fourth side transmission surface TA-S4 are extended along the second direction DR2 and may be spaced apart from each other in the first direction DR1 with the main transmission surface TA-M interposed therebetween.

The window WM may include first to fourth window corner portions W-C1, W-C2, W-C3, and W-C4 which are disposed between the first to fourth side transmission surfaces TA-S1, TA-S2, TA-S3 and TA-S4. The first to fourth window corner portions W-C1, W-C2, W-C3 and W-C4 may respectively correspond to the first to fourth corner portions C1, C2, C3 and C4 of the display device DD (See FIG. 1.). The first to fourth side transmission surfaces TA-S1, TA-S2, TA-S3 and TA-S4 and the first to fourth window corner portions W-C1, W-C2, W-C3 and W-C4 may be connected to each other respectively to surround the main transmission surface TA-M.

The first window corner portion W-C1 may be a portion connecting the first side transmission surface TA-S1 and the second side transmission surface TA-S2, where the respective first side transmission surface TA-S1 and the second side transmission surface TA-S2 are extended in directions intersecting each other and having a curvature. The second window corner portion W-C2 may be a portion connecting the second side transmission surface TA-S2 and the third side transmission surface TA-S3, where the respective second side transmission surface TA-S2 and the third side transmission surface TA-S3 are extended in directions intersecting each other and having a curvature. The third window corner portion W-C3 may be a portion connecting the third side transmission surface TA-S3 and the fourth side transmission surface TA-S4, where the respective third side transmission surface TA-S3 and the fourth side transmission surface TA-S4 are extended in directions intersecting each other and having a curvature. The fourth window corner portion W-C4 may be a portion connecting the fourth side transmission surface TA-S4 and the first side transmission surface TA-S1, where the respective fourth side transmission surface TA-S4 and the first side transmission surface TA-S1 are extended in directions intersecting each other and having a curvature.

Each of the window corner portions W-C1, W-C2, W-C3 and W-C4 connects the first and third side transmission surfaces TA-S1 and TA-S3, which are extended in the first direction DR1 and define short sides of the window WM, and the second and fourth side transmission surfaces TA-S2 and TA-S4, which are extended in the second direction DR2 intersecting the first direction DR1 and define long sides of the window WM, and thus, may be formed as multiple curvature points having different curvatures.

The display panel DP may be disposed below the window WM. The display panel DP may display an image in accordance with an electrical signal and may transmit and receive information on an external input depending on an embodiment. The display panel DP according to an embodiment may be a light emitting type display panel but is not particularly limited thereto. For example, the display panel DP may be an organic light emitting display panel, an inorganic light emitting display panel, a quantum dot light emitting display panel, or a combination thereof. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot, a quantum load, and the like, or a combination thereof. Hereinafter, the display panel DP will be described as an organic light emitting display panel.

The display panel DP may include a first portion P1 and a second portion P2. The first portion P1 and the second portion P2 may be adjacent portions in the second direction DR2. The second portion P2 may be a portion protruded and extended from the first portion P1 in the second direction DR2, and the first portion P1 and the second portion P2 may have a continuous shape (or, a shape of a single body). In other words, the first portion P1 and the second portion P2 may be a single monolithic piece. A monolithic piece is a single indivisible unitary piece which is not derived from an assembly of multiple units.

The first portion P1 of the display panel DP may include a main display portion D-M and at least one side display portion. FIG. 2 exemplarily illustrates an embodiment including first to fourth side display portions D-S1, D-S2, D-S3 and D-S4. The display panel DP may include first to fourth panel corner portions D-C1, D-C2, D-C3 and D-C4 which are disposed between the first to fourth side display portions D-S1, D-S2, D-S3 and D-S4.

The first portion P1 of the display panel DP may overlap the transmission region TA-M of the window WM. The first portion P1 of the display panel DP may comprise pixels. Specifically, the main display portion D-M, and the first to fourth side display portions D-S1, D-S2, D-S3 and D-S4 and the first to fourth panel corner portions D-C1, D-C2, D-C3, D-C4 may all comprise pixels. The main display portion D-M, the first to fourth side display portions D-S1, D-S2, D-S3 and D-S4, and the first to fourth panel corner portions D-C1, D-C2, D-C3 and D-C4 may be adjacent to each other and form a continuous single-body display region.

In the first portion P1 of the display panel DP, an arrangement form of the pixels may be variously designed. Each of the pixels may include a light emitting element and a pixel driving circuit connected to the light emitting element and including transistors (e.g., a switching transistor, a driving transistor, etc.) and at least one capacitor. Images output through the pixels disposed in the first portion P1 of the display panel DP may pass through the transmission region of the window WM and be visually recognized from the outside.

The main display portion D-M may include a plane substantially parallel to the plane defined by the first direction DR1 and the second direction DR2. The main display portion D-M may overlap the main transmission surface TA-M. The entire surface of the main display portion D-M may be provided as a display region. However, the embodiment of the invention is not limited thereto, and one portion of the main display portion D-M may be a non-display region.

Each of the first to fourth side display portions D-S1, D-S2, D-S3 and D-S4 may be extended from the main display portion D-M. Each of the first to fourth side display portions D-S1, D-S2, D-S3 and D-S4 may correspond to an edge of the display panel DP. The first to fourth side display portions D-S1, D-S2, D-S3 and D-S4 may respectively overlap with the first to fourth side transmission surfaces TA-S1, TA-S2, TA-S3 and TA-S4 of the window WM. The first to fourth side display portions D-S1, D-S2, D-S3 and D-S4 may be provided as a display region and may further include a non-display region adjacent to the display region depending on an embodiment.

When the display panel DP is coupled to the window WM, each of the first to fourth side display portions D-S1, D-S2, D-S3 and D-S4 may be extended from the main display portion D-M and bent and may include a curved surface having a curvature. The first side display portion D-S1 and the third side display portion D-S3 may be bent with respect to a bending axis parallel to the first direction DR1 so as to respectively correspond to the first side transmission surface TA-S1 and the third side transmission surface TA-S3. In an embodiment, the first side display portion D-S1 and the third side display portion D-S3 may be curved and are parallel to the curvature of the first side transmission surface TA-S1 and the third side transmission surface TA-S3 respectively. The second side display portion D-S2 and the fourth side display portion D-S4 may be bent with respect to a bending axis parallel to the second direction DR2 so as to respectively correspond to the second side transmission surface TA-S2 and the fourth side transmission surface TA-S4. In an embodiment, the second side display portion D-S2 and the fourth side display portion D-S4 may be curved and are parallel to the curvature of the second side transmission surface TA-S2 and the fourth side transmission surface TA-S4 respectively.

Each of the first side display portion D-S1 and the third side display portion D-S3 are extended along the first direction DR1 and may be spaced apart in the second direction DR2 with the main display portion D-M interposed therebetween. Each of the first side display portion D-S1 and the third side display portion D-S3 may define a short side of the display panel DP, the short side being parallel to the first direction DR1.

Each of the second side display portion D-S2 and the fourth side display portion D-S4 are extended along the second direction DR2 and may be spaced apart in the first direction DR1 with the main display portion D-M interposed therebetween. Each of the second side display portion D-S2 and the fourth side display portion D-S4 may define a long side of the display panel DP, the long side being parallel to the second direction DR2.

The first to fourth panel corner portions D-C1, D-C2, D-C3 and D-C4 may be respectively disposed between the first to fourth side display portions D-S1, D-S2, D-S3 and D-S4. The first to fourth panel corner portions D-C1, D-C2, D-C3 and D-C4 may respectively correspond to corners of the display panel DP. The first to fourth side display portions D-S1, D-S2, D-S3 and D-S4 and the first to fourth panel corner portions D-C1, D-C2, D-C3 and D-C4 may be connected to each other to surround the main display portion D-M. The first to fourth panel corner portions D-C1, D-C2, D-C3 and D-C4 may respectively overlap the first to fourth window corner portions W-C1, W-C2, W-C3 and W-C4 of the window WM. When the display panel DP is in communication with the window WM, each of the first to fourth panel corner portions D-C1, D-C2, D-C3 and D-C4 may be bent with a curvature that lies parallel to the curvature of the corner portions W-C1, W-C2, W-C3 and W-C4 respectively of the window WM.

The first panel corner portion D-C1 may be a portion connecting the first side display portion D-S1 and the second side display portion D-S2 which are extended in directions intersecting each other. Each of the first side display portion D-S1 and the second side display portion D-S2 may have a curvature. The second panel corner portion D-C2 may be a portion connecting the second side display portion D-S2 and the third side display portion D-S3 which are extended in directions intersecting each other. Each of the second side display portion D-S2 and the third side display portion D-S3 may have a curvature. The third panel corner portion D-C3 may be a portion connecting the third side display portion D-S3 and the fourth side display portion D-S4 which are extended in directions intersecting each other. Each of the third side display portion D-S3 and the fourth side display portion D-S4 may have a curvature. The fourth panel corner portion D-C4 may be a portion connecting the fourth side display portion D-S4 and the first side display portion D-S1 which are extended in directions intersecting each other. Each of the fourth side display portion D-S4 and the first side display portion D-S1 may have a curvature.

An outer edge of each of the first to fourth panel corner portions D-C1, D-C2, D-C3 and D-C4 may connect the short side of the display panel DP which is extended in the first direction DR1 and the long side of the display panel DP which is extended in the second direction DR2 and may have at least one curvature. That is, an outer side surface of each of the first to fourth panel corner portions D-C1, D-C2, D-C3 and D-C4 may include a curved surface having at least one curvature. According to an embodiment, the first to fourth panel corner portions D-C1, D-C2, D-C3 and D-C4 may be formed as multiple curvature points having different curvatures. The curvature of the first to fourth panel corner portions D-C1, D-C2, D-C3 and D-C4 may lie in a single 2-dimensional plane (i.e., where the 2-dimensional plane is in the direction of a plane that lies in the DR1 and DR2 directions) or may lie in 3-dimensions (i.e., where the 3-dimensional plane has components that lie in the DR1, DR2 and DR3 directions).

The second portion P2 is optional and may extend from the first side portion D-S1. The second portion P2 may extend in the second direction DR2 from a side surface of the first side display portion D-S1 (where D-S1 is parallel to the first direction DR1). The second portion P2 may be bent toward a rear surface of the display panel DP corresponding to the first portion P1 with respect to the bending axis parallel to the first direction DR1. As the second portion P2 is bent, the second portion P2 may overlap the first portion P1 on a plane.

In the first direction DR1, a width WT1 of the first portion P1 may be greater than a width WT2 of the second portion P2. Since the second portion P2 has a small width in a direction parallel to the bending axis, the second portion P2 may be easily bent. However, the embodiment of the invention is not limited thereto, and the second portion P2 of the display panel DP may be omitted. In this case, the side surface of the first side display portion D-S1 may correspond to an end of the display panel DP.

The protective film PF may be disposed on the rear surface of the display panel DP. The protective film PF may be disposed overlapping the first portion P1 of the display panel DP. The protective film PF may be attached to the rear surface of the display panel DP through an adhesive layer. The protective film PF may protect the rear surface of the display panel DP from being damaged during a process of manufacturing the display panel DP.

The protective film PF may include recessed patterns disposed adjacent to the panel corner portions D-C1, D-C2, D-C3 and D-C4. Since the recessed patterns are formed in the protective film PF, when the display panel DP is attached to the window WM, it is possible to prevent a buckling phenomenon in which the panel corner portions D-C1, D-C2, D-C3 and D-C4 of the display panel DP are attached while being wrinkled or have cracks. A detailed description thereof will be given later.

The driver DDV may be disposed on the second portion P2. The driver DDV may be a timing control circuit. The driver DDV may be provided as an integrated circuit chip (driving chip) mounted on the second portion P2. However, the embodiment of the invention is not limited thereto, and the driver DDV may be provided separately from the display panel DP and be mounted on a flexible circuit board electrically connected to the display panel DP.

The circuit board MB may be disposed on the second portion P2. In an embodiment, the circuit board MB may be disposed more adjacent to a lower end of the second portion than the driver DDV. The circuit board MB may be electrically connected to the second portion P2 to provide signals for driving the display panel DP. Since the second portion P2 is bent, the circuit board MB may be disposed overlapping the first portion P1 of the display panel DP on a plane. However, the embodiment of the invention is not limited thereto, and the circuit board MB may be directly connected to the first portion P1 or may be connected to the display panel DP through a separate flexible circuit board.

The anti-reflection layer POL is in communication with and may be disposed on the display panel DP. In an embodiment, the anti-reflection layer POL is in optical communication with the display panel DP. The anti-reflection layer POL may be directly disposed on the display panel DP without a separate adhesive member. That is, the anti-reflection layer POL may be formed on a base surface provided by the display panel DP through a continuous process. However, the embodiment of the invention is not limited thereto, and the anti-reflection layer POL may be coupled to the display panel DP through a separate adhesive member.

The anti-reflection layer POL may reduce reflectance of external light incident from an upper portion of the display device DD. The anti-reflection layer POL may include various embodiments for reducing the reflectance of external light.

The anti-reflection layer POL according to an embodiment may include a phase retarder and a polarizer. The phase retarder may include a 212 phase retarder and/or a 214 phase retarder. The phase retarder and the polarizer may each comprise a film or comprise a liquid crystal coating. The polarizer may include a stretchable synthetic resin film, and the liquid crystal coating polarizer may include liquid crystals arranged in a predetermined arrangement. However, the embodiment of the invention is not limited thereto, and the phase retarder and the polarizer may be implemented as one polarizing film (i.e., a single polarizing film).

The anti-reflection layer POL according to an embodiment may include a destructive interference structure. For example, the destructive interference structure may include a first reflection layer and a second reflection layer disposed on different layers. First reflected light reflected from the first reflection layer and second reflected light reflected from the second reflection layer may undergo destructive interference, and accordingly, the anti-reflection layer POL may reduce the reflectance of external light.

The anti-reflection layer POL according to an embodiment may include color filters. The color filters may be disposed to correspond to the arrangement and emission colors of the pixels included in the display panel DP. The anti-reflection layer POL may filter the external light incident from the upper portion of the display device DD to a color corresponding to the emission colors of the pixels. The anti-reflection layer POL may further include a black matrix adjacent to the color filters.

The adhesive member AM may be disposed between the anti-reflection layer POL and window WM. The display panel DP and the anti-reflection layer POL may be in communication with the window WM through the adhesive member AM. The adhesive member AM may be an optically transparent adhesive member such as a pressure sensitive adhesive film (PSA), an optically clear adhesive film (OCA), or an optically clear resin (OCR).

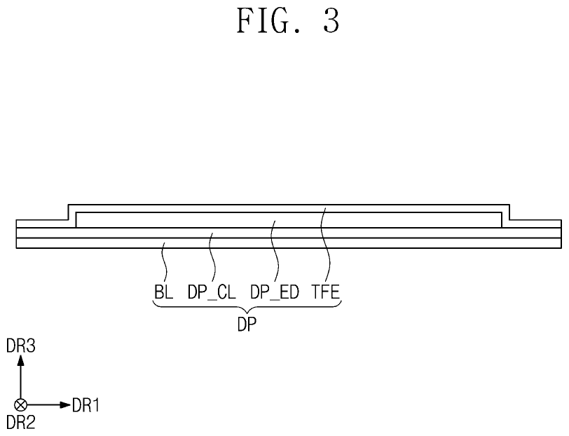

FIG. 3 is a cross-sectional view of the display panel DP according to an embodiment of the invention.

Referring to FIG. 3, the display panel DP may include a base layer BL, a circuit layer DP_CL, a display element layer DP_ED, and an encapsulation layer TFE.

The base layer BL may provide a base surface on which the circuit layer DP_CL is disposed. The base layer BL may be a rigid substrate, or a flexible substrate capable of bending, folding, rolling, or the like. For example, the base layer BL may be a glass substrate, a metal substrate, a polymer substrate, or the like.

The base layer BL may have a multi-layered structure. For example, the base layer BL may include synthetic resin layers and at least one inorganic layer disposed between the synthetic resin layers. The synthetic resin layer of the base layer BL may include at least one of an acrylic resin, a methacrylic resin, a polyisoprene, a vinyl-based resin, an epoxy-based resin, a urethane-based resin, a cellulose-based resin, a siloxane-based resin, a polyimide-based resin, a perylene-based resin, a polyimide-based resin, or a combination thereof. However, materials of base layer BL are not limited to the above examples.

The circuit layer DP_CL may be disposed on the base layer BL. The circuit layer DP_CL may include an insulating pattern, a semiconductor pattern, and a conductive pattern for forming a pixel driving circuit, a driving wiring, and a pad of a pixel. In a manufacturing step of the display panel DP, an insulation layer, a semiconductor layer, and a conductive layer may be formed on the base layer BL by coating, deposition, or the like, and thereafter, the insulation layer, the semiconductor layer, and the conductive layer may be selectively patterned through performing photolithography a plurality of times to form the circuit layer DP-CL.

The display element layer DP_ED may be disposed on the circuit layer DP_CL. The display element layer DP_ED may include light emitting elements that form the pixel. The light emitting elements may be in electrical communication with the pixel driving circuit of the circuit layer DP_CL. The light emitting elements may include an organic light emitting element, an inorganic light emitting element, a micro-light-emitting diode (LED), a nano-light-emitting diode (LED), or the like, and are not limited to any one thereof as long as the amount of light is controllable via an electrical signal.

The encapsulation layer TFE may be disposed on the light emitting element layer DP_ED to encapsulate the display element layer DP_ED. The encapsulation layer TFE may include at least one thin film for improving optical efficiency of the display element layer DP_ED, or for protecting the display element layer DP_ED. For example, the encapsulation layer TFE may include at least one of an inorganic film, an organic film, or a combination thereof. The inorganic film of the encapsulation layer TFE may protect the display element layer DP_ED from moisture/oxygen. The organic film of the encapsulation layer TFE may protect the display element layer DP_ED from foreign substances such as dust particles.

The inorganic film of the encapsulation layer TFE may include at least one of an aluminum oxide, a titanium oxide, a silicon oxide, a silicon nitride, a silicon oxynitride, a zirconium oxide, a hafnium oxide, or a combination thereof. The organic film of the encapsulation layer TFE, may include an acrylic resin, a methacrylic resin, a polyisoprene, a vinyl-based resin, an epoxy-based resin, a urethane-based resin, a cellulose-based resin, a siloxane-based resin, a polyimide-based resin, a perylene-based resin, a polyimide-based resin, or a combination thereof. However, materials of the encapsulation layer TFE are not limited to the above examples.

Meanwhile, the display panel DP may further include an input sensing layer (not shown) disposed on the encapsulation layer TBE to sense external inputs. The input sensing layer may be directly disposed on the encapsulation layer TFE. The input sensing layer may be formed on an upper surface of the encapsulation layer TFE through a continuous process. However, the embodiment of the invention is not limited thereto, and the input sensing layer may be disposed on the encapsulation layer TFE through a separate adhesive member.

The input sensing layer (not shown) may obtain the coordinate information of an external input applied from the outside of the display device DD (see FIG. 1). The external input may include various forms of inputs such as force, pressure, temperature, light, or the like. For example, the external input may include an input by a user's hand or an electronic pen which contacts with the display device DD (see FIG. 1), or an input applied in close proximity to the display device DD (see FIG. 1) such as hovering.

The input sensing layer may be driven in various ways to sense the external input applied from the outside of the display device DD (see FIG. 1). For example, the input sensing layer may operate in a capacitance method, a resistive film method, an infrared method, a sound wave method, a pressure method, or the like, and is not limited to any one thereof as long as an external input is sensed.

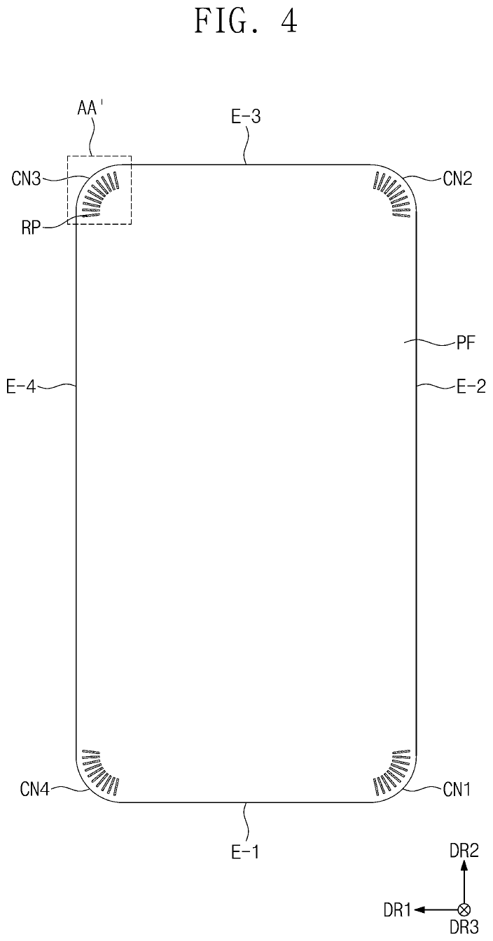

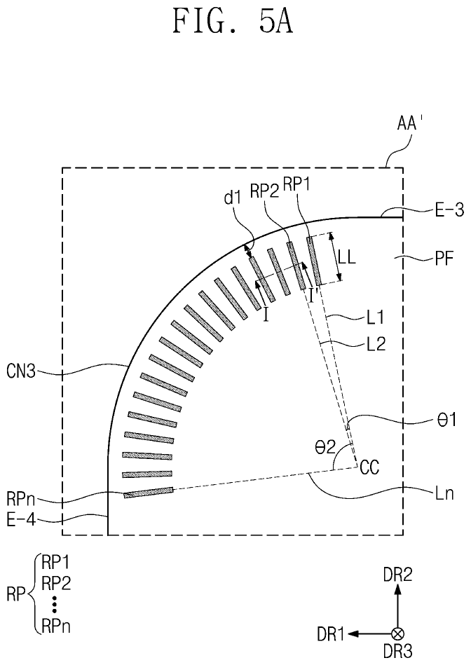

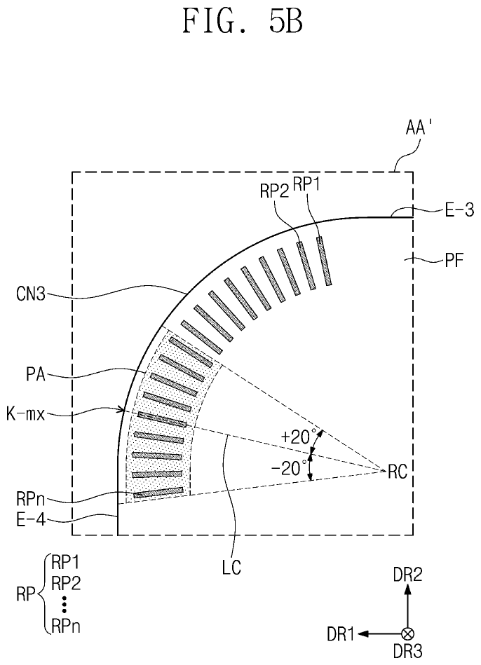

FIG. 4 is a plan view of a protective film PF according to an embodiment of the invention. FIG. 5A and FIG. 5B are plan views of the protective film PF in which one region AA′ of FIG. 4 is enlarged. FIG. 4, FIG. 5A and FIG. 5B illustrate plan views of the protective film PF viewed from a rear surface of the protective film PF.

Referring to FIG. 2 and FIG. 4, the protective film PF may be disposed on the rear surface of the display panel DP. The protective film PF may be disposed on the rear surface of the display panel DP which corresponds to the first portion P1 (see FIG. 2.). The protective film PF may cover the entire region of the rear surface of the first portion P1 (see FIG. 2.) of the display panel DP. Accordingly, an outer side surface of the protective film PF may be aligned with an outer side surface of the first portion P1 (see FIG. 2.) of the display panel DP.

The protective film PF may include first to fourth edges E-1, E-2, E-3 and E-4 and first to fourth corners CN1, CN2, CN3 and CN4 connecting the first to fourth edges E-1, E-2, E-3 and E-4 respectively.

Each of the first edge E-1 and the third edge E-3 may be extended along the first direction DR1. The first edge E-1 may be aligned with an outer side surface of the first side display portion D-S1 of the display panel DP (see FIG. 2). The third edge E-3 may be aligned with an outer side surface of the third side display portion D-S3 of the display panel DP (see FIG. 2).

Each of the second edge E-2 and the fourth edge E-4 may be extended along the second direction DR2. The second edge E-2 may be aligned with an outer side surface of the second side display portion D-S2 of the display panel DP (see FIG. 2). The fourth edge E-4 may be aligned with an outer side surface of the fourth side display portion D-S4 of the display panel DP (see FIG. 2).

The first corner CN1 may connect the first edge E-1 and the second edge E-2. The second corner CN2 may connect the second edge E-2 and the third edge E-3. The third corner CN3 may connect the third edge E-3 and the fourth edge E-4. The fourth corner CN4 may connect the fourth edge E-4 and the first edge E-1.

The first to fourth corners CN1, CN2, CN3 and CN4 may respectively correspond to corners of the protective film PF. The first to fourth corners CN1, CN2, CN3 and CN4 may each have at least one curvature and may connect intersecting sides of the protective film PF. The first to fourth corners CN1, CN2, CN3 and CN4 may be formed as multiple curvature points having different curvatures. As a result, the corners of the protective film PF may have a round shape.

Referring to FIGS. 2 and 4 together, the first corner CN1 may correspond to the first panel corner portion D-C1 of the display panel DP. The second corner CN2 may correspond to the second panel corner portion D-C2 of the display panel DP. The third corner CN3 may correspond to the third panel corner portion D-C3 of the display panel DP. The fourth corner CN4 may correspond to the fourth panel corner portion D-C4 of the display panel DP. The first to fourth corners CN1, CN2, CN3 and CN4 may be respectively aligned with the outer side surfaces of the first to fourth panel corner portions D-C1, D-C2, D-C3 and D-C4.

The protective film PF may include recessed patterns RP formed by removing a portion of the protective film PF. The recessed patterns RP may be disposed adjacent to the first to fourth corners CN1, CN2, CN3 and CN4. That is, the recessed patterns RP may be disposed spaced apart from a central portion of the protective film PF. The recessed patterns RP may be disposed overlapping the first to fourth panel corner portions D-C1, D-C2, D-C3 and D-C4 (see FIG. 2).

The recessed patterns RP may be arranged along the first to fourth corners CN1, CN2, CN3 and CN4. Each of the recessed patterns RP may have a shape in which the recessed patterns RP are extended along one direction on a plane. For example, each of the recessed patterns RP may be extended along a direction intersecting each of the first direction DR1 and the second direction DR2 on a plane. The recessed patterns RP may be extended toward a center of curvature of an adjacent corner of the protective film PF.

Since the recessed patterns RP are adjacent to the first to fourth corners CN1, CN2, CN3 and CN4 and disposed on rear surfaces of the first to fourth panel corner portions D-C1, D-C2, D-C3, D-C4, when the display panel DP is attached to the window WM, it is possible to prevent the panel corner portions D-C1, D-C2, D-C3 and D-C4 from being wrinkled (during assembly) due to a limited space within the window WM, or from having cracks due to stress.

FIG. 5A and FIG. 5B illustrate one region AA′ corresponding to the third corner CN3 of the protective film PF. Hereinafter, descriptions of the third corner CN3 and recessed patterns RP disposed adjacent to the third corner CN3 may be equally applied to the rest of the corners (e.g., the first, second, and fourth corners CN1, CN2, and CN4) and recessed patterns RP adjacent thereto. For convenience of description, hereinafter, the third corner CN3 may be referred to as the corner CN3.

Referring to FIG. 5A and FIG. 5B, a plurality of recessed patterns RP: RP1 to RPn (where “n” is an integer) may be disposed adjacent to one corner CN3. The recessed patterns RP may be arranged corresponding to a shape in which the corner CN3 is curved. For example, a virtual line connecting centers of the recessed patterns RP may correspond to a shape of an outer side surface of the corner CN3.

The recessed patterns RP may include first to n-th recessed patterns RP1 to RPn. Although FIG. 5A and FIG. 5B exemplarily illustrate an embodiment in which the n corresponds to 18, the number of the recessed patterns RP is not limited thereto.

The first recessed pattern RP1 corresponding to the first among the recessed patterns RP may be disposed adjacent to a point where a curve (that forms the corner) starts from the third edge E-3 parallel to the first direction DR1. The second to the n-th recessed patterns RP2 to RPn may be arranged corresponding to the corner CN3 from the first recessed pattern RP1. The n-th recessed pattern RPn corresponding to the n-th among the recessed patterns RP may be disposed adjacent to a point where a curve (that forms the corner) starts from the fourth edge E-4 parallel to the second direction DR2.

Each of the recessed patterns RP may be have a stripe shape in which the recessed patterns RP are extended along one direction. Each of the recessed patterns RP may be extended in a direction different from extension directions of the third edge E-3 and the fourth edge E-4. For example, each of the recessed patterns RP may be extended along a direction intersecting each of the first direction DR1 and the second direction DR2 on a plane. Extension directions of the recessed patterns RP may be different from each other. For example, an extension direction of the first recessed pattern RP1 and an extension direction of the second recessed pattern RP2 are different from each other. The extension directions of the recessed patterns RP may substantially correspond to directions from one point on the corner CN3 toward one point CC in the protective film PF, respectively. For example, each of the recessed patterns RP may be extended in a direction from one point on the corner CN3 toward the center of curvature CC of the corner CN3.

A disposition interval at which the recessed patterns RP are disposed may be designed to have a predetermined angle between adjacent recessed patterns RP. For example, adjacent recessed patterns RP may be disposed to have an interval of about 3 degrees (°) or greater. Specifically, when an angle between a first reference line L1 extended from the center of the first recessed pattern RP1 and a second reference line L2 extended from the center of the second recessed pattern RP2 is a first angle Θ1, the first recessed pattern RP1 and the second recessed pattern RP2 may be defined as having an interval of the first angle Θ1, wherein the first angle Θ1 may be 3 degrees (°) or greater. By controlling the disposition interval of the recessed patterns RP, it is possible to minimize wrinkles of the display panel DP (see FIG. 2) and reduce stress applied to the display panel DP (see FIG. 2) when the display panel DP (see FIG. 2) is attached to the window WM (see FIG. 2).

Depending on regions in which the recessed patterns RP are disposed, the degree to which the display panel DP (see FIG. 2) is wrinkled or the degree of stress applied to the display panel DP (see FIG. 2) may vary when the display panel DP (see FIG. 2) is attached to the window WM (see FIG. 2). Depending on a second angle Θ2, which is an angle between the first reference line L1 extended from the center of the first recessed pattern RP1 and an n-th reference line Ln extended from the center of the n-th recessed pattern RPn, the disposition regions of the recessed patterns RP may vary. For example, the second angle Θ2 may be about 65 degrees (°) or greater, and specifically, may be close to about 85 degrees (°).

The regions in which the recessed patterns RP are disposed may be related to the curvature of the corner CN3. Referring to FIG. 5B, the outer side surface of the corner CN3 may have curvatures of 2 or greater (i.e., there are 2 or more types of curvature), and may have a maximum curvature at a specific point. In the present embodiment, a point of the outer side surface of the corner CN3 that has the maximum curvature may be defined as a maximum curvature point K-mx. The disposition of the recessed patterns RP may be designed such that the recessed patterns RP are disposed within a region PA of ±20 degrees (°) or greater with respect to a reference line LC connecting a curvature center RC from the maximum curvature point K-mx. If the recessed patterns RP are disposed only in a region less than 20 degrees (°) with respect to the reference line LC, or if the recessed patterns RP are disposed in other regions, the effect of preventing a buckling problem of the display panel DP (see FIG. 2) through the recessed patterns RP may decrease.

Referring to FIG. 5A, the recessed patterns RP may have the same length LL in an extension direction. The recessed patterns RP may have the same width in a direction perpendicular to the extension direction. However, the embodiment is not limited thereto, and at least some of the recessed patterns RP may have lengths LL different from each other, or may have widths different from each other. The lengths LL and widths of the recessed patterns RP may be adjusted according to curvatures of the panel corner portions D-C1, D-C2, D-C3, and D-C3 of the display panel DP (see FIG. 2) and the window corner portions W-C1, W-C2, W-C3, and W-C4 of the window WM (see FIG. 2).

The recessed patterns RP may be formed inside the protective film PF. That is, the recessed patterns RP may be surrounded by the protective film PF on a plane. The recessed patterns RP may be disposed within the protective film PF at a distance dl from the outer side surface of the corner CN3 (see FIG. 5A). However, the embodiment of the invention is not necessarily limited thereto.

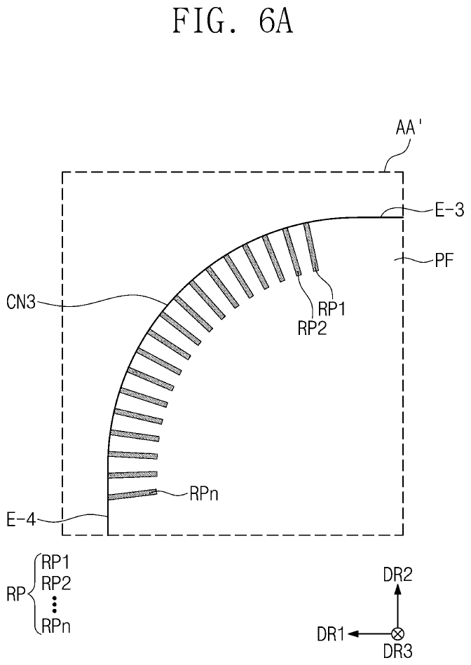

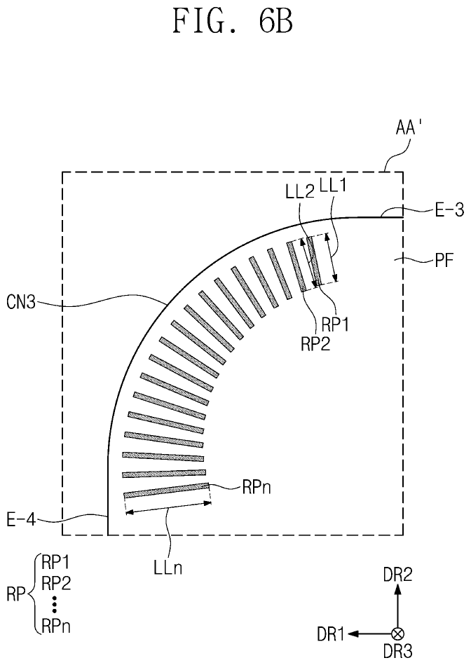

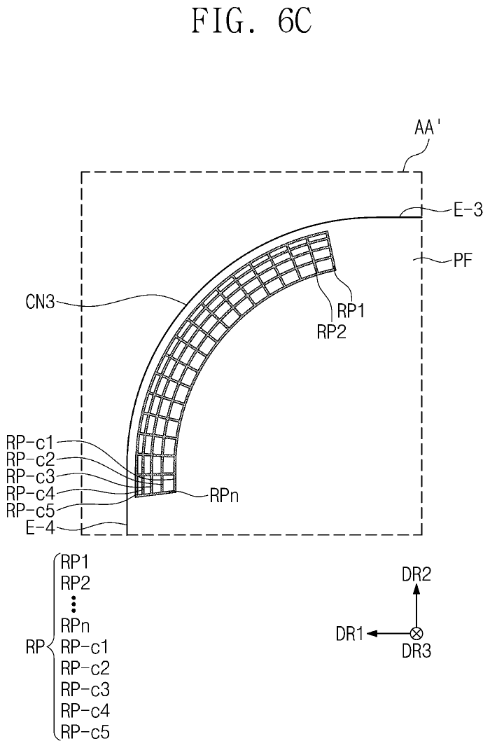

FIG. 6A to FIG. 6C are plan views of the protective film PF according to an embodiment of the invention. FIG. 6A to FIG. 6C illustrate plan views of the protective film PF corresponding to one region AA′ of FIG. 4. Embodiments illustrated in FIG. 6A to FIG. 6C are partially different from the embodiment of FIG. 5A in the disposition or shape of the recessed patterns RP, and otherwise the above description may be equally applied.

Referring to FIG. 6A, the recessed patterns RP may be extended to the outer side surface of the protective film PF. For example, the recessed patterns RP may be extended to the outer side surface of the corner CN3. Accordingly, a portion of the protective film PF on the outer side surface of the corner CN3 may have a lesser thickness due to the recessed patterns RP than the rest of the protective film.

Referring to FIG. 6B, the recessed patterns RP may have different lengths from each other in the extension direction. The lengths of the recessed patterns RP may vary according to a curvature at which a side display portion of the display panel DP (see FIG. 2) is bent. The recessed pattern RP disposed adjacent to a side display portion bent with a greater curvature may have a greater length.

For example, a side display portion (e.g., the second and fourth side display portions D-S2 and D-S4 (see FIG. 2)) corresponding to a long side of the display panel DP (see FIG. 2) may be bent with a greater curvature than a side display portion (e.g., the first and third side display portions D-S1 and D-S3 (see FIG. 2)) corresponding to a short side thereof. As a result, as in the embodiment illustrated in FIG. 6B, the length of the recessed pattern RP adjacent to a side display portion corresponding to a long side may be greater than the length of the recessed pattern RP adjacent to a side display portion corresponding to a short side on the plane. That is, the length of the recessed patterns RP may increase from the third edge E-3 corresponding to a short side as closer to the fourth edge E-4 corresponding to a long side. Specifically, among the recess patterns RP, a length LL1 of the first recessed pattern RP1 most adjacent to the third edge E-3 may be smaller than a length L2 of the second recessed pattern RP2. A length of LLn of the n-th recessed pattern RPn most adjacent to the fourth edge E-4 may be the greatest among the recessed patterns RP. The term “n” represents an integer.

However, the embodiment of the invention is not limited thereto, and according to a curvature at which the side display portions D-S1, D-S2, D-S3 and D-S4 (see FIG. 2) are bent, the lengths of the recessed patterns RP may increase with the proximity to the edge corresponding to a long side. In other words, the length of the recessed patterns are smaller (with regard to the average length of the recessed patterns RP) when located adjacent to an edge corresponding to a short side and are longer (with regard to the average length of the recessed patterns RP) when located adjacent to an edge corresponding to a long side.

Referring to FIG. 6C, the recessed patterns RP may have a mesh shape. For example, the recessed patterns RP may further include connection recess patterns RP-c1 to RP-c5 intersecting and connected to the first to the n-th recessed patterns RP1 to RPn described above. The connection recess patterns RP-c1 to RP-c5 may include first to fifth connection recess patterns RP-c1 to RP-c5. However, the number of connection recessed patterns is exemplary, and is not limited to any one embodiment as long as the recessed patterns RP have a mesh shape.

The first connection recessed pattern RP-c1 may be connected to one end(s) of the first to n-th recessed patterns RP1 to RPn. The fifth connection recessed pattern RP-c5 may be connected to the other end(s) (the opposite end(s)) of the first to n-th recessed patterns RP1 to RPn. Among the first to fifth connection recessed patterns RP-c1 to RP-c5, the fifth connection recessed pattern RP-c5 may be disposed most adjacent to the outer side surface of the corner CN3.

Among the connection recessed patterns RP-c1 to RP-c5, an interval between adjacent connection recessed patterns may get smaller as closer to the corner CN3. However, the embodiment of the invention is not limited thereto, and the interval between the first to the second, the second to the third, and so on to the fifth connection recessed patterns RP-c1 to RP-c5 may be the same.

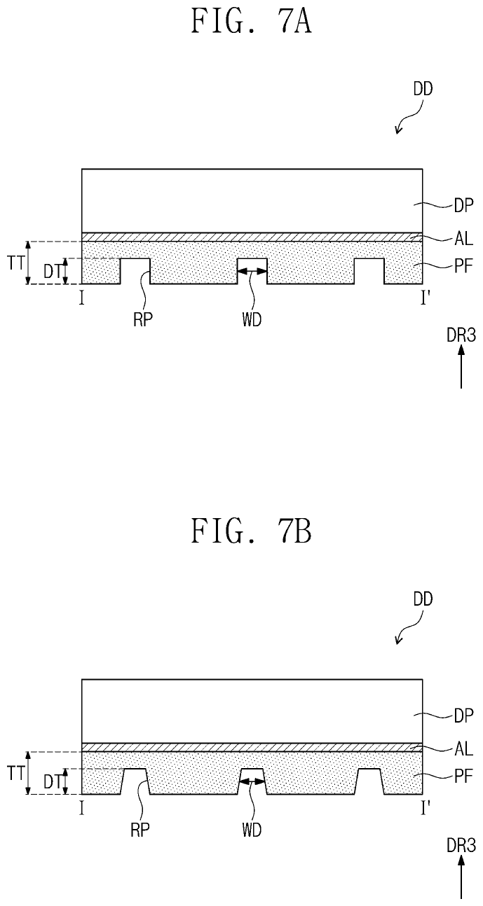

FIG. 7A and FIG. 7B are cross-sectional views of the display device DD according to an embodiment of the present invention. FIG. 7A and FIG. 7B are cross-sectional views of the display device DD corresponding to line I-I′ of FIG. 5A.

Referring to FIG. 7A and FIG. 7B, the display device DD may include the display panel DP and the protective film PF, and the description of each component may be the same as that described above.

The protective film PF is in communication with the display panel DP through an adhesive layer AL. The adhesive layer AL may include an optically clear adhesive such as a pressure sensitive adhesive film, an optically clear adhesive film, or an optically clear adhesive resin.

The protective film PF may include an upper surface in contact with the adhesive layer AL and a lower surface opposite to the upper surface. The upper surface of the protective film PF may be more adjacent to the rear surface of the display panel DP than the lower surface of the protective film PF.

The recessed patterns RP may be formed recessed from the lower surface of the protective film PF toward the upper surface thereof. For example, the recessed patterns RP may be formed by removing a portion of the protective film PF by using a laser etching. Other methods such as chemical etching may also be used to form the recessed patterns. However, the method for forming the recessed patterns RP is not limited thereto.

Referring to FIG. 7A, a width WD of the recessed patterns RP may be constant along the third direction DR3. A depth DT of the recessed patterns RP may be equal to or less than a thickness TT of the protective film PF. Accordingly, the formation of the recessed patterns RP may not affect the adhesive layer AL, and the recessed patterns RP may overlap the adhesive layer AL on a plane.

Referring to FIG. 7B, the width WD of the recessed patterns RP may vary along the third direction DR3. For example, the width WD of the recessed patterns RP may decrease from the lower surface of the protective film PF as closer to the upper surface thereof. Shapes of the recessed patterns RP on a cross-section may vary according to process conditions for forming the recessed patterns RP.

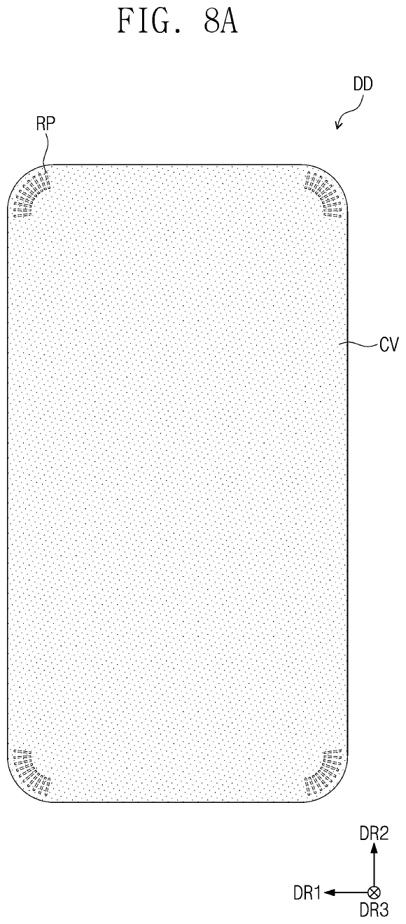

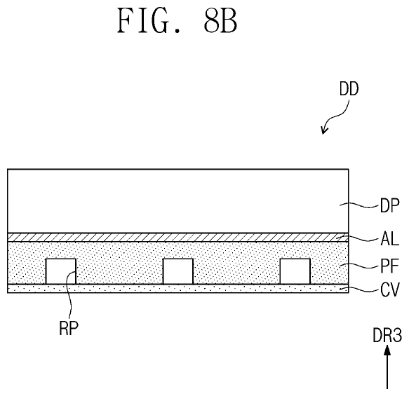

FIG. 8A is a plan view of the display device DD according to an embodiment of the invention. FIG. 8B is a cross-sectional view of the display device DD according to an embodiment of the invention. FIG. 8A is a plan view of the display device DD viewed on the rear surface of the protective film PF (see FIG. 4).

Referring to FIG. 8A and FIG. 8B, the display device DD may further include a lower member CV. The lower member CV may be disposed on the lower surface of the protective film PF. The lower member CV overlaps the recessed patterns RP on a plane, and may cover the recessed patterns RP. The lower member CV may be disposed on a lower portion of the display panel DP to protect the display panel DP.

The lower member CV may include a light blocking layer. The light blocking layer may include a light blocking material to prevent reflected light from being transmitted to the outside. For example, the light blocking layer may include a binder with pigment particles such as carbon black dispersed therein. The light blocking layer may prevent components disposed on the rear surface of the display panel DP from being visually recognized from the outside. In addition, the light blocking layer of the lower member CV may prevent the recessed patterns RP formed in the protective film PF from being visually recognized from the outside.

The lower member CV may further include at least one of a heat dissipation layer and a cushion layer. The heat dissipation layer may dissipate heat generated from elements disposed on the lower portion of the display panel DP to protect the display panel DP. The heat dissipation layer may include a material such as stainless steel, graphite, copper, or aluminum having good heat dissipation properties. The heat dissipation layer may have electromagnetic wave shielding or electromagnetic wave absorption properties in addition to heat dissipation properties, and may prevent noise from being generated in the display panel DP.

The cushion layer may absorb an external impact applied to the rear surface of the display panel DP. The cushion layer may include a material having elasticity. For example, the cushion layer may include a synthetic resin foam having a porous structure. A plurality of pores dispersed in the cushion layer may absorb an external impact to improve the impact resistance of the display panel DP.

### EXAMPLES

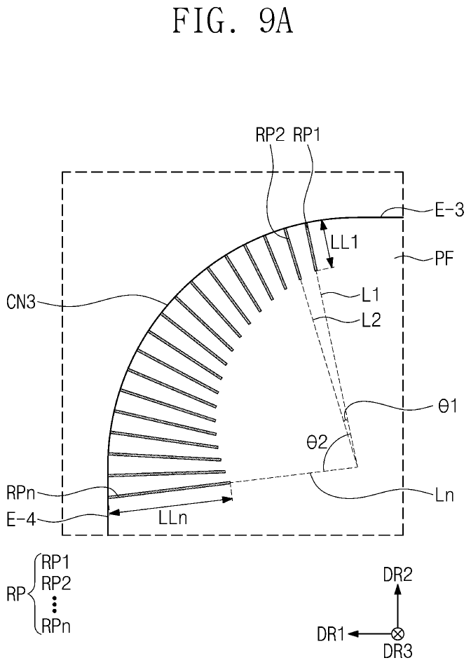

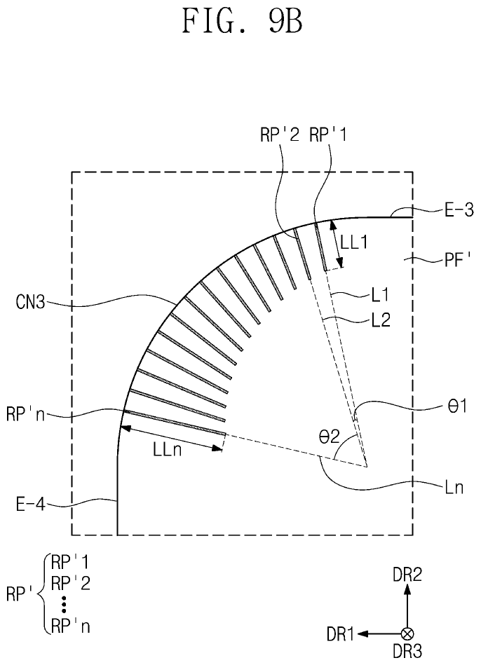

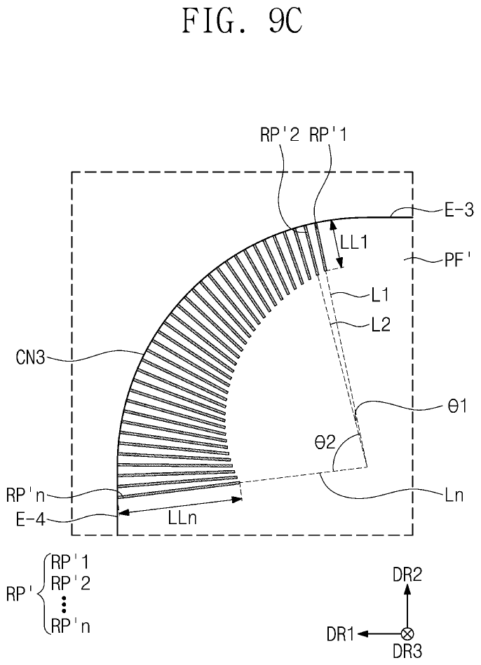

This example is conducted to demonstrate the protective film of the invention versus comparative protective films. FIG. 9A is a plan view of the protective film PF according to an embodiment of the invention. FIG. 9B and FIG. 9C are plan views of a protective film PF′ according to a comparative embodiment of the invention.

Referring to FIG. 9A, recessed patterns RP may include first to n-th recessed patterns RP1 to RPn. The first to n-th recessed patterns RP1 to RPn may be extended to an outer side surface of the protective film PF. Lengths of the first to n-th recessed patterns RP1 to RPn may increase as the first to n-th recessed patterns RP1 to RPn are disposed more adjacent to a fourth edge E-4 from a third edge E-3. Among the first to n-th recessed patterns RP1 to RPn, a length LL1 of the first recessed pattern RP1 most adjacent to the third edge E-3 may be the smallest, and a length LLn of the n-th recessed pattern RPn most adjacent to the fourth edge E-4 may be the largest. As may be seen in the FIG. 9A, the recessed patterns may contact the surface of the corner CN3.

A second angle Θ2, which is an angle between a first reference line L1 extended from the center of the first recessed pattern RP1 and an n-th reference line Ln extended from the center of the n-th recessed pattern RPn, may be about 65 to about 85 degrees (°). A first angle Θ1 corresponding to an interval between adjacent recessed patterns among the first to n-th recessed patterns RP1 to RPn may be 5 degrees (°).

Referring to FIG. 9B and FIG. 9C, in the comparative embodiment, recessed patterns RP′ may include first to n-th recessed patterns RP′ 1 to RP′n. The first to n-th recessed patterns RP′ 1 to RP′n may be extended to an outer side surface CN3 of the protective film PF′. Lengths of the first to n-th recessed patterns RP′ 1 to RP′n may increase as the first to n-th recessed patterns RP′ 1 to RP′n are disposed more adjacent to a fourth edge E-4 from a third edge E-3. Among the first to n-th recessed patterns RP′ 1 to RP′n, a length LL1 of the first recessed pattern RP′ 1 most adjacent to the third edge E-3 (a smaller edge compared with edge E-4) may be the smallest, and a length LLn of the n-th recessed pattern RP′ n most adjacent to the fourth edge E-4 (a larger edge compared with edge E-3) may be the largest.

In the comparative embodiment of FIG. 9B, the number of recessed patterns RP′ disposed adjacent to one corner CN3 may be smaller than the number of recessed patterns RP of the embodiment illustrated in FIG. 9A. In the comparative embodiment of FIG. 9B, a second angle Θ2, which is an angle between a first reference line L1 extended from the center of the first recessed pattern RP′ 1 and an n-th reference line Ln extended from the center of the n-th recessed pattern RP′n, may be about 65 degrees (°). A first angle Θ1 corresponding to an interval between adjacent recessed patterns among the first to n-th recessed patterns RP′ 1 to RP′n may be 5 degrees (°).

In the comparative embodiment of FIG. 9C, the number of recessed patterns RP′ disposed adjacent to one corner CN3 may be larger than the number of the recessed patterns RP of the embodiment illustrated in FIG. 9A. That is, the density of the recessed patterns RP′ of the comparative embodiment may be greater than the density of the recessed patterns RP of the embodiment within the same region. In the comparative embodiment of FIG. 9C, a second angle Θ2, which is an angle between a first reference line L1 extended from the center of the first recessed pattern RP′ 1 and an n-th reference line Ln extended from the center of the n-th recessed pattern RP′ n, may be about 85 degrees (°). A first angle Θ1 corresponding to an interval between adjacent recessed patterns among the first to n-th recessed patterns RP′ 1 to RP′n may be 2.5 degrees (°).

[Table 1] below shows ‘wrinkles,’‘cracks,’ and ‘compression strain’ generated in a region corresponding to a panel corner portion when a display panel on which the protective film of each of Example 1 and Comparative Examples 1 to 3 is disposed is attached to a window. In [Table 1], the smaller the numbers of ‘wrinkles and cracks,’ the smaller the degree to which wrinkles are generated and cracks are formed, and the smaller the absolute value of ‘compression strain’, the smaller the degree to which a display panel is deformed corresponding to a panel corner portion.

Example 1 includes a display panel on which the protective film PF illustrated in FIG. 9A is disposed. Comparative Example 1 includes a display panel on which a protective film without recessed patterns is disposed. Comparative Example 2 includes a display panel on which the protective film PF′ illustrated in FIG. 9B is disposed. Comparative Example 3 includes a display panel on which the protective film PF′ illustrated in FIG. 9C is disposed.

TABLE 1

| | | Comparative | Comparative | Comparative |
|---|---|---|---|---|
| | Example 1 | Example 1 | Example 2 | Example 3 |
| Wrinkle | 0.92 | 2.40 | 2.03 | 2.93 |
| Crack | 0.56 | 0.62 | 0.65 | 0.59 |
| Compression | −2.44 | −2.89 | −3.18 | −3.00 |
| strain | | | | |

When comparing the values of wrinkles, cracks, and compression strains of Example 1 and Comparative Examples 1 to 3, Example 1 may solve the problem in which wrinkles or cracks are generated on a display panel when attaching a window to the display panel, and the problem in which the display panel is deformed corresponding to a panel corner portion.

When comparing Example 1 with Comparative Example 1, it is possible to prevent a display panel from being damaged when attaching the display panel to a window since the recessed patterns RP are formed in the protective film PF rather than without recessed patterns in a protective film.

When comparing Example 1 with Comparative Example 2, a region in which the recessed patterns RP are disposed in Example 1 may be further extended than a region in which the recessed patterns RP′ are disposed in Comparative Example 2. The protective film PF′ of Comparative Example 2 may include a region in which the recessed patterns RP′ are not disposed within a region of a range of ±20 degrees) (° with respect to a reference line connecting a maximum curvature point of a corner and the center of curvature thereof, and as a result, stress may be concentrated in a region adjacent to a panel corner portion of the display panel. Accordingly, wrinkles or cracks generated in the display panel of Comparative Example 2 may increase. However, in the case of Example 1, since the recessed patterns RP are disposed in the extended region, stress may be prevented from being concentrated in a region adjacent to a panel corner portion.

When comparing Example 1 with Comparative Example 3, a region in which the recessed patterns RP are disposed in Example 1 is substantially the same as a region in which the recessed patterns RP′ are disposed in Comparative Example 3, but the density of the recessed patterns RP′ of Comparative Example 3 may be larger than that of Example 1. When the density of the recessed patterns RP′ is excessively large, wrinkles or cracks generated in the display panel may increase. Therefore, the reliability of the display panel may be improved by adjusting the disposition interval and number of the recessed patterns RP to an appropriate range.

A display device according to an embodiment includes a protective film coupled onto a rear surface of a display panel, wherein the protective film may include recessed patterns in correspondence to a corner portion of a window. During a process in which the display panel and the window are coupled, the protective film having the recessed patterns is attached to the rear surface of the display panel, so that the display panel may be prevented from being wrinkled due to a limited space corresponding to the corner portion of the window, or from being damaged due to concentration of stress on the display panel. Accordingly, the reliability of the display device may be improved.

Although the present invention has been described with reference to preferred embodiments of the present invention, it will be understood by those skilled in the art that various modifications and changes in form and details may be made therein without departing from the spirit and scope of the present invention as set forth in the following claims.

Accordingly, the technical scope of the present invention is not intended to be limited to the contents set forth in the detailed description of the specification, but is intended to be defined by the appended claims.

What is claimed is:

1. A display device comprising:
a display panel; and
a protective film attached to a rear surface of the display panel through an adhesive layer,
wherein the display panel includes:
a first side extended in a first direction;
a second side extended in a second direction intersecting the first direction; and
a panel corner portion connecting the first side and the second side and having a curvature,
wherein the protective film includes recessed patterns disposed adjacent to the panel corner portion and overlapping the adhesive layer.

2. The display device of claim 1, wherein the recessed patterns are disposed at an inner side and at a distance dl from an outer side surface of the protective film.

3. The display device of claim 1, wherein the recessed patterns are extended to an outer side surface of the protective film on a plane.

4. The display panel of claim 1, wherein the recessed patterns are disposed within a region of ±20 degrees or more based on a line connecting a center of curvature from a point of maximum curvature of the panel corner portion.

5. The display device of claim 1, wherein each of the recessed patterns has a stripe shape in which the recessed patterns are extended along a direction intersecting each of the first direction and the second direction on a plane.

6. The display device of claim 5, wherein each of the recessed patterns are extended in a direction toward a center of curvature of the panel corner portion from one point of an edge of the panel corner portion.

7. The display device of claim 6, wherein an angle between reference lines parallel to extension directions of recessed patterns adjacent to each other among the recessed patterns is 3 degrees or more.

8. The display device of claim 6, wherein the recessed patterns comprise first to n-th recessed patterns, wherein an angle between a first reference line parallel to an extension direction of the first recessed pattern and a n-th reference line parallel to an extension direction of the n-th recessed pattern is 65 degrees or more, and the n is a natural number of 2 or greater.

9. The display device of claim 1, wherein the recessed patterns have a mesh shape in which the recessed pattern are connected by intersecting each other on a plane.

10. The display device of claim 1, wherein in a thickness direction, a depth of each of the recessed patterns is equal to or less than a thickness of the protective film.

11. The display device of claim 10, wherein a width of each of the recessed patterns is constant along the thickness direction.

12. The display device of claim 10, wherein a width of each of the recessed patterns decreases with proximity to the display panel.

13. The display device of claim 1, wherein the display panel comprises:
a main display portion parallel to the first direction and the second direction;
a first side display portion extended from the main display portion in the second direction and curved; and
a second side display portion extended from the main display portion in the first direction and curved, wherein the first side and the second side are respectively defined in the first side display portion and the second side display portion.

14. The display device of claim 1, wherein the display panel includes:
a base layer;
a circuit layer disposed on the base layer;
a display element layer disposed on the circuit layer and including light emitting elements; and
an encapsulation layer disposed on the display element layer, wherein the protective film is attached to the base layer.

15. The display device of claim 1, further comprising a light blocking layer disposed below the protective film and overlapping the recessed patterns.

16. The display device of claim 1, further comprising a window disposed on the display panel, and an adhesive member disposed between the display panel and the window.

17. A display device comprising:
a display panel including a panel corner portion having at least one curvature; and
a protective film disposed on a rear surface of the display panel and including recessed patterns adjacent to the panel corner portion, wherein the recessed patterns are disposed within a region of ±20 degrees or more based on a line connecting the center of curvature from a point of maximum curvature of the panel corner portion.

18. The display device of claim 17, wherein the recessed patterns comprise first to n-th recessed patterns arranged along one direction, wherein an angle between a first reference line parallel to an extension direction of the first recessed pattern and a n-th reference line parallel to an extension direction of the n-th recessed pattern is 65 degrees or more, and the n is a natural number of 2 or greater.

19. The display device of claim 18, wherein an angle between reference lines parallel to extension directions of recessed patterns adjacent to each other among the first to n-th recessed patterns is 3 degrees or more.

20. The display device of claim 17, wherein the recessed patterns have a stripe shape or a mesh shape.
